(19) United States
(12) Patent Application Publication
(10) Pub. No.: US 2026/0293649 A1
(43) Pub. Date: Sep. 24, 2026

(54) INTEGRATED CIRCUIT DEVICES INCLUDING STACKED TRANSISTORS WITH THROUGH-EPI CONNECTIVITY

(71) Applicant: Samsung Electronics Co., Ltd., Suwon-si (KR)

(72) Inventors: Jinyoung Lim, Schenectady, NY (US); Edward Namkyu Cho, Slingerlands, NY (US); Young Gook Park, Resselaer, NY (US); Hyo Jong Shin, Mechanicville, NY (US); Kang-ill Seo, Springfield, VA (US)

(21) Appl. No.: 19/333,520

(22) Filed: Sep. 19, 2025

Related U.S. Application Data
(60) Provisional application No. 63/773,753, filed on Mar. 18, 2025.

(51) Int. Cl. H01L 23/528; H10D 84/83; H10D 89/10

(52) U.S. Cl. CPC H10W 20/435; H10D 84/83125; H10D 89/10; H10W 20/427; H10W 20/43

(57) ABSTRACT

An integrated circuit device may include a substrate and a cell structure on an upper surface of the substrate. The cell structure may comprise a first epitaxial layer on the upper surface of the substrate, a second epitaxial layer stacked on the first epitaxial layer in a first direction that is perpendicular to the upper surface of the substrate, a front-side conductive track on an upper portion of the cell structure, and a back-side conductive track on a lower portion of the cell structure opposite to the upper portion of the cell structure in the first direction. The first epitaxial layer and the second epitaxial layer may be between the front-side conductive track and the back-side conductive track in the first direction. The back-side conductive track may be electrically connected to the front-side conductive track through the second epitaxial layer.

### CROSS-REFERENCE TO RELATED APPLICATIONS

The present application claims the benefit of U.S. Provisional Patent Application Ser. No. 63/773,753, filed on Mar. 18, 2025, entitled STACKED TRANSISTORS WITH POWER DELIVERY SCHEME (THROUGH-EPI POWER TAB) BETWEEN BACK-SIDE POWER DELIVERY NETWORK AND FRONT-SIDE POWER DELIVERY NETWORK AND METHODS OF MANUFACTURING THE SAME, the disclosure of which is hereby incorporated herein in its entirety by reference.

### BACKGROUND

The present disclosure generally relates to the field of integrated circuit devices and, more particularly, to integrated circuit devices including stacked transistors.

Various structures of an integrated circuit device and methods of forming the same have been proposed to increase the integration degree of the integrated circuit device. For example, a stacked transistor structure including multiple transistors vertically stacked has been proposed.

The stacked transistor structure may be in an I-shape scheme, an L-shape scheme, or a Z-shape scheme in a cross-sectional view. In the I-shape scheme, an upper transistor and a lower transistor may have (substantially) the same size (e.g., (substantially) the same cell height or (substantially) the same channel width) and may be aligned with each other in a horizontal direction. In the L-shape scheme, an upper transistor and a lower transistor may have different sizes (e.g., different cell heights or different channel widths) from each other. In the L-shape scheme, one of sidewalls of the upper transistor and one of sidewalls of the lower transistor may be aligned in a horizontal direction, and another one of the sidewalls of the upper transistor and another one of the sidewalls of the lower transistor may not be aligned in the horizontal direction. In the Z-shape scheme, one of sidewalls of a lower transistor may overlap an upper transistor in the vertical direction, and another one of the sidewalls of the lower transistor may not overlap the upper transistor in the vertical direction.

The stacked transistor structure may include a back-side power delivery network (BSPDN) on a lower surface of the lower transistor to further improve the integration degree, power level, and performance of the integrated circuit device. The BSPDN may supply power to the upper transistor and/or the lower transistor.

In some applications, power may need to be delivered between the BSPDN and a front-side power delivery network (FSPDN) on an upper surface of the upper transistor. The stacked transistor structure may include a middle-of-line (MOL) structure, comprising conductive vias and conductive contacts to provide connectivity (e.g., electrical connectivity) between the BSPDN and the FSPDN.

To further increase the integration degree of the integrated circuit device and reduce the contact resistance among the elements thereof, a contact of the MOL structure between the BSPDN and the lower transistor in the vertical direction may be (completely) overlapped by the lower transistor in the vertical direction without a detour in a space between the lower transistor (e.g., the sidewall of the lower transistor facing the adjacent cell boundary) and the adjacent cell boundary in a horizontal direction. The configuration of the contact of the MOL structure between the lower transistor and the BSPDN without the detour may be referred to as a direct back-side contact (DBC) scheme.

In the DBC scheme, however, the connectivity between the BSPDN and the FSPDN may be interfered as the lower transistor is positioned between the BSPDN and the FSPDN in the vertical direction.

### SUMMARY

An aspect of the present disclosure is to provide at least a portion of the stacked transistor structure (e.g., the lower transistor, the lower epitaxial layer, or the lower source/drain layer) as at least a portion of a power tab cell (e.g., a through-epi contact) to deliver power between the BSPDN and the FSPDN. The stacked transistor structure may be configured to function as the power tab cell distinguishing power domains between the BSPDN and the FSPDN. For example, the stacked transistor structure (the power tab cell) may distinguish the power domain of the BSPDN from the power domain of the FSPDN. The BSPDN may be configured to function as a global power distribution network, and the FSPDN may be configured to function as a local distribution network. Power may be supplied from the global power distribution network to the local distribution network. However, the embodiments of the configuration of the power tab cell are not limited thereto. For example, the stacked transistor structure (the power tab cell) may distinguish the power domain of the BSPDN, which is a local power distribution network, from the power domain of the FSPDN, which is a global power distribution network.

An integrated circuit device, according to some embodiments, may include a substrate and a cell structure on an upper surface of the substrate. The cell structure may comprise a first epitaxial layer on the upper surface of the substrate, a second epitaxial layer stacked on the first epitaxial layer in a first direction that is perpendicular to the upper surface of the substrate, a front-side conductive track on an upper portion of the cell structure, and a back-side conductive track on a lower portion of the cell structure opposite to the upper portion of the cell structure in the first direction. The first epitaxial layer and the second epitaxial layer may be between the front-side conductive track and the back-side conductive track in the first direction. The back-side conductive track may be electrically connected to the front-side conductive track through the second epitaxial layer.

An integrated circuit device, according to some embodiments, may include a substrate and a cell structure on an upper surface of the substrate. The cell structure may comprise a first transistor including a first source/drain layer on the upper surface of the substrate, a second transistor including a second source/drain layer stacked on the first source/drain layer in a first direction that is perpendicular to the upper surface of the substrate, front-side power rails on an upper portion of the cell structure, and back-side power rails on a lower portion of the cell structure. The first source/drain layer and the second source/drain layer may be between the front-side power rails and the back-side power rails in the first direction. At least one of the back-side power rails may be electrically connected to at least one of the front-side power rails through the second source/drain layer.

An integrated circuit device, according to some embodiments, may include a substrate, a first cell structure on an upper surface of the substrate, a second cell structure adjacent the first cell structure in a first direction that is parallel with the upper surface of the substrate, and a cell boundary between the first cell structure and the second cell structure in the first direction. The first cell structure may comprise a first transistor including a first epitaxial layer on the upper surface of the substrate, a second transistor including a second epitaxial layer stacked on the first epitaxial layer in a second direction that is perpendicular to the upper surface of the substrate, front-side conductive tracks on an upper surface of the first transistor, and back-side conductive tracks on a lower surface of the second transistor. At least one of the back-side conductive tracks may be electrically connected to at least one of the front-side conductive tracks through the second epitaxial layer. The second transistor may be configured to be inoperable.

### BRIEF DESCRIPTION OF THE DRAWINGS

FIGS. 1A and 1B are a plan view and a cross-sectional view of an integrated circuit device with a lower through-epi connectivity according to some embodiments, respectively.

FIGS. 2A and 2B are a plan view and a cross-sectional view of an integrated circuit device with a lower through-epi connectivity and a shared front-side conductive track according to some embodiments, respectively.

FIGS. 3A and 3B are a plan view and a cross-sectional view of an integrated circuit device illustrating multiple cell structures with a lower through-epi connectivity and a shared front-side conductive track according to some embodiments, respectively.

FIGS. 4A and 4B are a plan view and a cross-sectional view of an integrated circuit device with a lower through-epi connectivity, an upper through-epi connectivity, and a shared front-side conductive track according to some embodiments, respectively.

### DETAILED DESCRIPTION OF EMBODIMENTS

Pursuant to embodiments herein, an integrated circuit device may include an upper transistor and a lower transistor in a L-shape scheme or a Z-shape scheme. However, the embodiments of the integrated circuit device are not limited thereto. Example embodiments will be described in greater detail with reference to the attached figures.

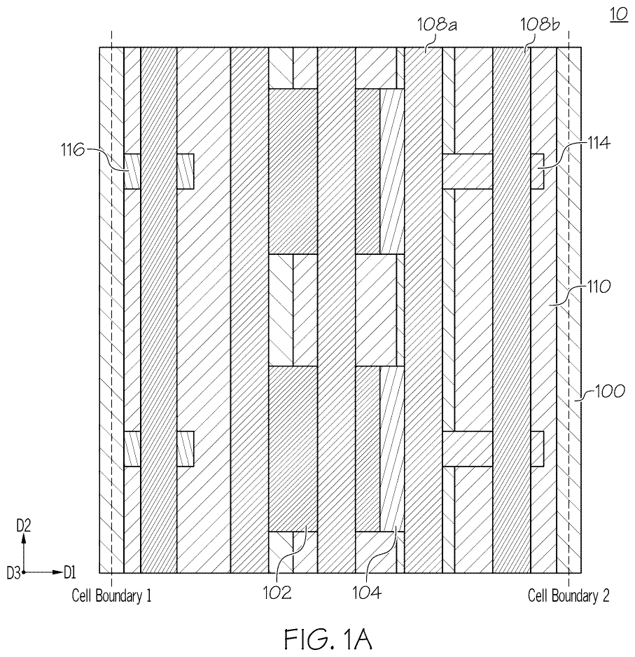

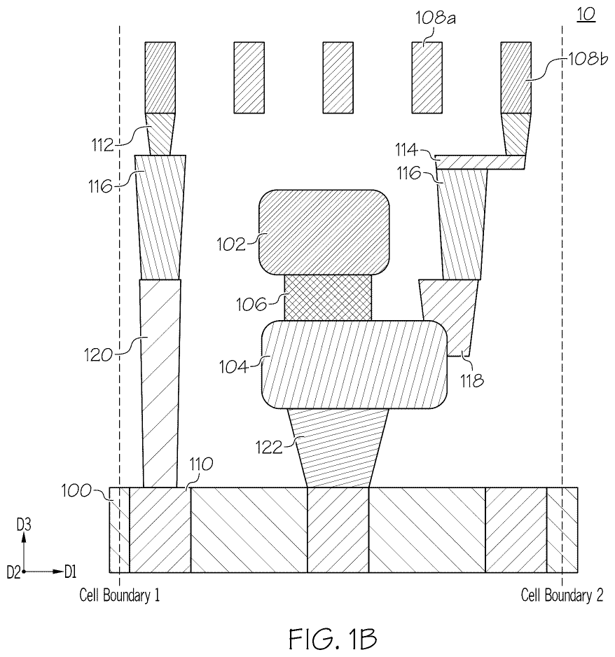

FIGS. 1A and 1B are a plan view and a cross-sectional view of an integrated circuit device 10 with a lower through-epi connectivity according to some embodiments, respectively. FIG. 1A may be a plan view from an upper side of the integrated circuit device 10. For example, FIG. 1A may be a bird's eye view of the top of the integrated circuit device 10. FIG. 1B may be a cross-sectional view (e.g., along the first direction D1) of the integrated circuit device 10 illustrated in FIG. 1A.

Referring to FIGS. 1A and 1B, the integrated circuit device 10 may include a first cell structure on a substrate 100. The integrated circuit device 10 may have a first cell boundary (e.g., cell boundary 1 in FIGS. 1A and 1B) and a second cell boundary (e.g., cell boundary 2 in FIGS. 1A and 1B) that is spaced apart from the first cell boundary in a horizontal direction that is parallel with an upper surface of the substrate 100. For example, the first cell boundary and the second cell boundary may be spaced apart from each other in a first direction D1 that is parallel with the upper surface of the substrate 100. The first cell structure may be between the first cell boundary and the second cell boundary in the first direction D1. The second cell boundary may be opposite to the first cell boundary with respect to the first cell structure in the first direction D1. For example, the first cell structure may refer to a region that includes various elements of the integrated circuit device 10 between the first cell boundary and the second cell boundary in the first direction D1.

The substrate 100 may include semiconductor material(s), for example, Si, Ge, SiGe, GaP, GaAs, SiC, SiGeC and/or InP and/or may include insulating material(s), for example, silicon oxide, silicon oxynitride, silicon nitride, silicon carbonitride and/or a low-k material. In some embodiments, the substrate may be a bulk substrate (e.g., a silicon wafer), a semiconductor on insulator (SOI) substrate or an insulating layer (e.g., a monolithic insulating layer). The low-k material may have a lower dielectric constat than that of silicon oxide (e.g., SiO). The low-k material may include, for example, fluorine-doped silicon oxide, organosilicate glass, carbon-doped oxide, porous silicon dioxide, porous organosilicate glass, spin-on organic polymeric dielectrics and/or spin-on silicon based polymeric dielectric.

Referring to FIGS. 1A and 1B, the first cell structure of the integrated circuit device 10 may include a first transistor 102 (e.g., an upper transistor 102) and a second transistor 104 (e.g., a lower transistor 104) formed on the substrate 100. Herein, the first transistor 102 may refer to a first epitaxial layer (e.g., a first source/drain layer) therein, and the second transistor 104 may refer to a second epitaxial layer (e.g., a second source/drain layer) therein. The first transistor 102 and the second transistor 104 may comprise a stacked transistor structure. The first transistor 102 may be an upper portion of the first cell structure, and the second transistor 104 may be a lower portion of the first cell structure. The second transistor 104 may be between (the upper surface of) the substrate 100 and the first transistor 102 in a vertical direction that is perpendicular to the upper surface and/or a lower surface of the substrate 100. Herein, the vertical direction may refer to a third direction D3 in the drawings. In some embodiments, the first transistor 102 (e.g., the first epitaxial layer or the first source/drain layer, which will be described in detail below) and the second transistor 104 (e.g., the second epitaxial layer or the second source/drain layer, which will be described in detail below) may have different widths in the first direction D1. For example, the width in the first direction D1 of the second transistor 104 (e.g., the second epitaxial layer or the second source/drain layer) may be greater than the width in the first direction D1 of the first transistor 102 (e.g., the first epitaxial layer or the first source/drain layer). The center (or a central portion) of the first transistor 102 (e.g., the first epitaxial layer or the first source/drain layer) and the center (or a central portion) of the second transistor 104 (e.g., the second epitaxial layer or the second source/drain layer) may not overlap (e.g., may be misaligned with) each other in the third direction D3. For example, the center (or the central portion) of the first transistor 102 (e.g., the first epitaxial layer or the first source/drain layer) and the center (or the central portion) of the second transistor 104 (e.g., the second epitaxial layer or the second source/drain layer) may be offset from each other in the first direction D1. In some embodiments, the first transistor 102 (e.g., the first epitaxial layer or the first source/drain layer) may have a first sidewall and a second sidewall that is opposite to the first sidewall in the first direction D1, and the second transistor 104 (e.g., the second epitaxial layer or the second source/drain layer) may have a third sidewall and a fourth sidewall that is opposite to the third sidewall in the first direction D1. In some embodiments, a plane of the second sidewall of the first transistor 102 may be between respective planes of the third sidewall and the fourth sidewall of the second transistor 104 in the first direction D1. A plane of the first sidewall of the first transistor 102 may be aligned with the plane of the third sidewall of the second transistor 104 in the first direction D1. A plane of the fourth sidewall of the second transistor 104 may be free of overlap with respective planes of the first sidewall and the second sidewall of the first transistor 102 in the third direction D3. The fourth sidewall of the second transistor 104 may be free of overlap with the first transistor 102 in the third direction D3. In summary, the first transistor 102 may not have a portion that is free of overlap with the second transistor 104 in the third direction D3 (e.g., the first transistor 102 may be completely overlapped by the second transistor 104 in the third direction D3), but the second transistor 104 may have a portion that is free of overlap with the first transistor 102 in the third direction D3. The configuration of the first transistor 102 and the second transistor 104 described above may be referred to as a L-shape scheme or a L-shape 3D stacked device (e.g., L-shape 3D stacked field effect transistor (L-shape 3DSFET)).

The first transistor 102 and the second transistor 104 may have different conductivity types or the same conductivity type. In some embodiments, the first transistor 102 may include a first epitaxial layer. The first transistor 102 may be a P-type transistor, and the first epitaxial layer may be a P-type epitaxial layer. The second transistor 104 may include a second epitaxial layer (e.g., a second source/drain layer). The second transistor 104 may be an N-type transistor, and the second epitaxial layer may be an N-type epitaxial layer. However, the inventive concepts of the types of the first transistor 102 and the second transistor 104 are not limited to the embodiments described above. For example, the first transistor 102 may be an N-type transistor including an N-type epitaxial layer, and the second transistor 104 may be a P-type transistor including a P-type epitaxial layer. The first transistor 102 and the second transistor 104 may be implemented using various types of transistors (e.g., a planar transistor, a gate-all-around field-effect transistor (GAA FET), a recessed channel array transistor (RCAT), a fin field-effect transistor (FinFET), or multi-bridge-channel field effect transistor (MBCFET™)). In some embodiments, at least one of the first transistor 102 and the second transistor 104 may be inoperable. For example, at least one of the first transistor 102 and the second transistor 104 may not operate as a switch. At least one of the first transistor 102 and the second transistor 104 may not be switched between a conductive state (e.g., a more-conductive state) and a non-conductive state (e.g., a less-conductive state).

The first transistor 102 may comprise first channel layers (e.g., upper channel layers) (not illustrated) on (a sidewall of) the first epitaxial layer (e.g., the first source/drain layer) and a first work function layer (e.g., an upper work function layer) (not illustrated) on the first channel layers. The first transistor 102 may further comprise first gate insulators (e.g., upper gate insulators) (not illustrated) on the first channel layers, and a first gate electrode (e.g., an upper gate electrode) (not illustrated) on the first work function layer. For example, the first gate insulators may be between the first channel layers and the first work function layer. The first gate insulators, the first work function layer, and the first gate electrode may be collectively referred to as a first gate structure (e.g., an upper gate structure).

The first channel layers may be spaced apart from each other in the vertical direction (e.g., in the third direction D3). In some embodiments, the first channel layers may be spaced apart from each other at equal or substantially equal distance in the vertical direction. In some embodiments, each of the first channel layers may have an equal or a substantially equal width in the first direction D1 and a second direction D2 that is parallel with an upper surface of the substrate and intersects the first direction D1. The second direction D2 may be perpendicular to the first direction D1. Herein, “substantially” may mean no greater than a 10% deviation. For example, when element X has a width of 10 nm and a width of element Y is substantially equal to that of element X, the width of element Y may not be less than 9 nm or greater than 11 nm.

The first gate insulators may extend around (e.g., at least partially surround) the first channel layers, respectively. The first work function layer may extend around (e.g., at least partially surround) the first gate insulators (and the first channel layers). The first gate electrode may extend around (e.g., at least partially surround) the first work function layer.

In some embodiments, the first channel layers may include semiconductor material(s), for example, Si, Ge, SiGe, GaP, GaAs, SiC, SiGeC and/or InP. In some embodiments, the first gate insulators may include insulator(s), for example, silicon oxide, silicon oxynitride, silicon nitride, silicon carbonitride and/or a low-k material that has a lower dielectric constant than that of silicon oxide. In some embodiments, the first work function layer may include, for example, a TiN layer, a TaN layer, a TiAl layer, a TiC layer, a TiAlC layer, a TiAlN layer and/or a WN layer. In some embodiments, the first gate electrode may include, for example, tungsten (W), aluminum (Al) and/or copper (Cu). However, the materials of the first channel layers, the first gate insulators, the first work function layer, and the first gate electrode are not limited to the embodiments described above. In some embodiments, the first channel layers, the first gate insulators, the first work function layer, and the first gate electrode may be omitted.

The second transistor 104 may comprise second channel layers (e.g., lower channel layers) (not illustrated) on (a sidewall of) the second epitaxial layer (e.g., the second source/drain layer) and a second work function layer (e.g., a lower work function layer) (not illustrated) on the second channel layers. The second transistor 104 may further comprise second gate insulators (e.g., lower gate insulators) (not illustrated) on the second channel layers, and a second gate electrode (e.g., a lower gate electrode) (not illustrated) on the second work function layer. For example, the second gate insulators may be between the second channel layers and the second work function layer. The second gate insulators, the second work function layer, and the second gate electrode may be collectively referred to as a second gate structure (e.g., a lower gate structure).

The second channel layers may be spaced apart from each other in the vertical direction (e.g., in the third direction D3). In some embodiments, the second channel layers may be spaced apart from each other at equal or substantially equal distance in the vertical direction. In some embodiments, each of the second channel layers may have an equal or a substantially equal width in the first direction D1 and/or the second direction D2. In some embodiments the width of the first channel layers in the first direction D1 may be less than the width of the second channel layers in the first direction D1. In some embodiments, the width of the first channel layers in the second direction D2 may be (substantially) the same as the width of the second channel layers in the second direction D2. However, the relative widths of the first channel layers and the second channel layers in the first direction D1 and the second direction D2 are not limited thereto.

The second gate insulators may extend around (e.g., at least partially surround) the second channel layers, respectively. The second work function layer may extend around (e.g., at least partially surround) the second gate insulators. The second gate electrode may extend around (e.g., at least partially surround) the second work function layer.

In some embodiments, the second channel layers may include semiconductor material(s), for example, Si, Ge, SiGe, GaP, GaAs, SiC, SiGeC and/or InP. In some embodiments, the second gate insulators may include insulator(s), for example, silicon oxide, silicon oxynitride, silicon nitride, silicon carbonitride and/or a low-k material that has a lower dielectric constant than that of silicon oxide. In some embodiments, the second work function layer may include, for example, a TiN layer, a TaN layer, a TiAl layer, a TiC layer, a TiAlC layer, a TiAlN layer and/or a WN layer. In some embodiments, the second gate electrode may include, for example, tungsten (W), aluminum (Al) and/or copper (Cu). However, the materials of the second channel layers, the second gate insulators, the second work function layer, and the second gate electrode are not limited to the embodiments described above. In some embodiments, the second channel layers, the second gate insulators, the second work function layer, and the second gate electrode may be omitted.

In some embodiments, each of the first channel layers and the second channel layers may be a nanosheet (that may have a thickness in a range of from 1 nm to 100 nm in the vertical direction) or may be a nanowire (that may have a circular cross-section with a diameter in a range of from 1 nm to 100 nm). The number of the first channel layers and the number of the second channel layers may vary.

The integrated circuit device 10 may include an insulator 106 (also referred to as an inter-gate insulator 106 or a middle dielectric isolation 106) between the first transistor 102 and the second transistor 104 in the third direction D3. The insulator 106 may include insulator(s), for example, silicon nitride (e.g., SiN). However, the material of the insulator 106 is not limited thereto.

The integrated circuit device 10 may include front-side conductive tracks 108 on (the upper surface of) the first transistor 102. The front-side conductive tracks 108 may be spaced apart from each other in the first direction D1. Although not illustrated, an interlayer insulating layer may extend around (e.g., at least partially surround) the front-side conductive tracks 108. The front-side conductive tracks 108 may be spaced apart from each other by (substantially) the same distance in the first direction D1. In some embodiments, the front-side conductive tracks 108 may be spaced apart from each other by different distances in the first direction D1. In some embodiments, each of the front-side conductive tracks 108 may have the same or substantially the same width in the first direction D1. In some embodiments, one of the front-side conductive tracks 108 may have a width in the first direction D1 different from a width of another one of the front-side conductive tracks 108 in the first direction D1. In some embodiments, the distance between adjacent ones of the front-side conductive tracks 108 in the first direction D1 may be equal or substantially equal to the width of one of the front-side conductive tracks 108 in the first direction D1.

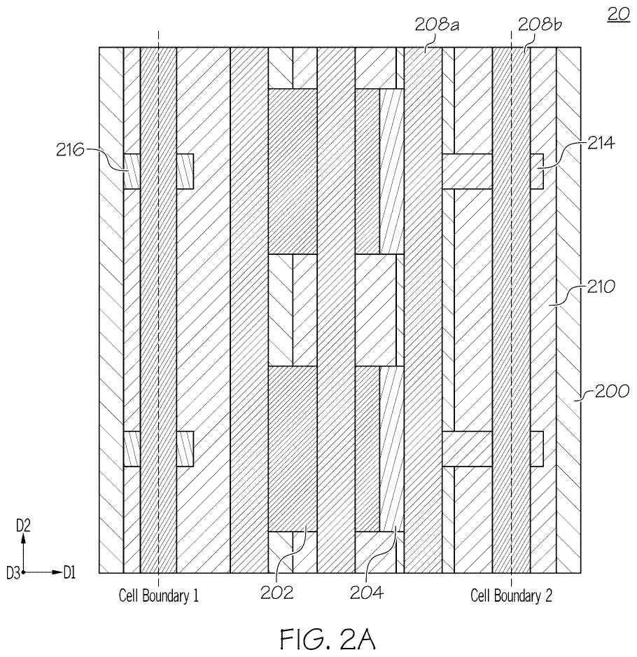

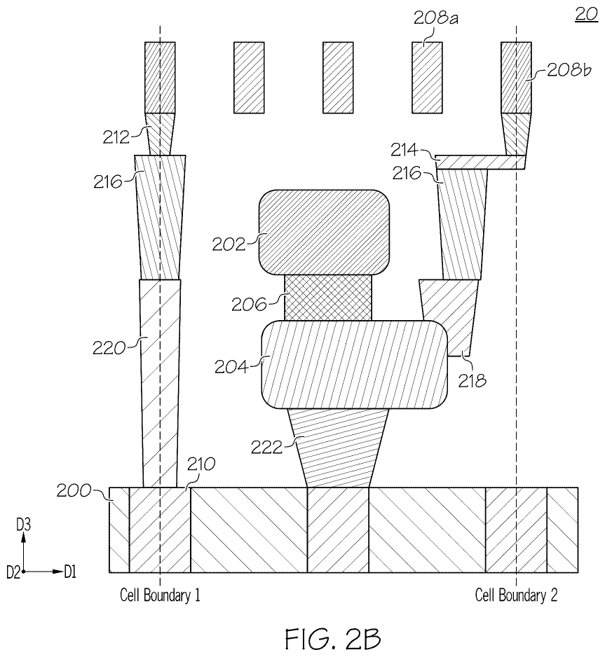

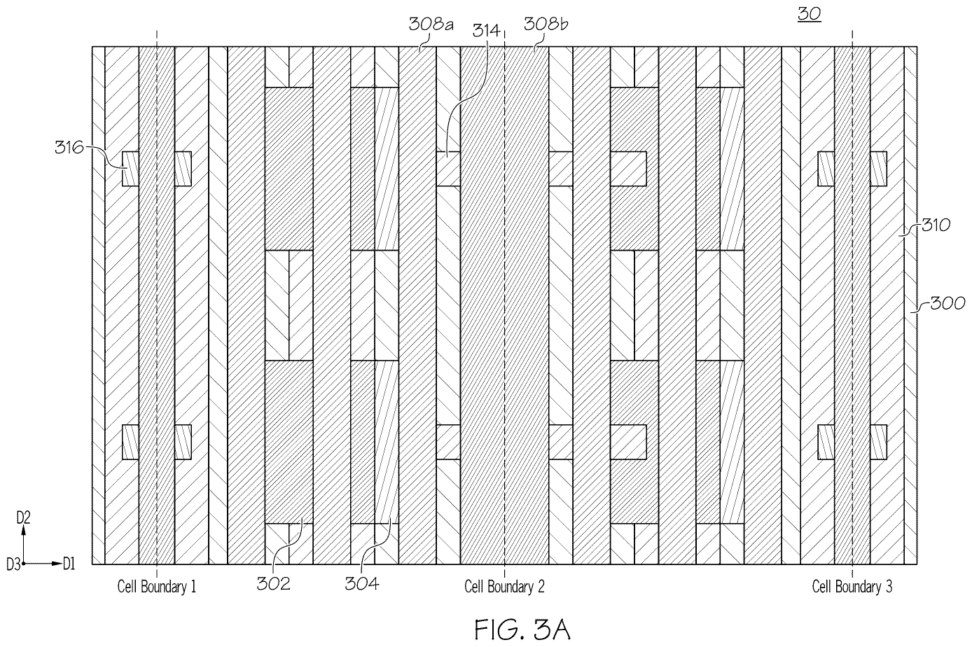

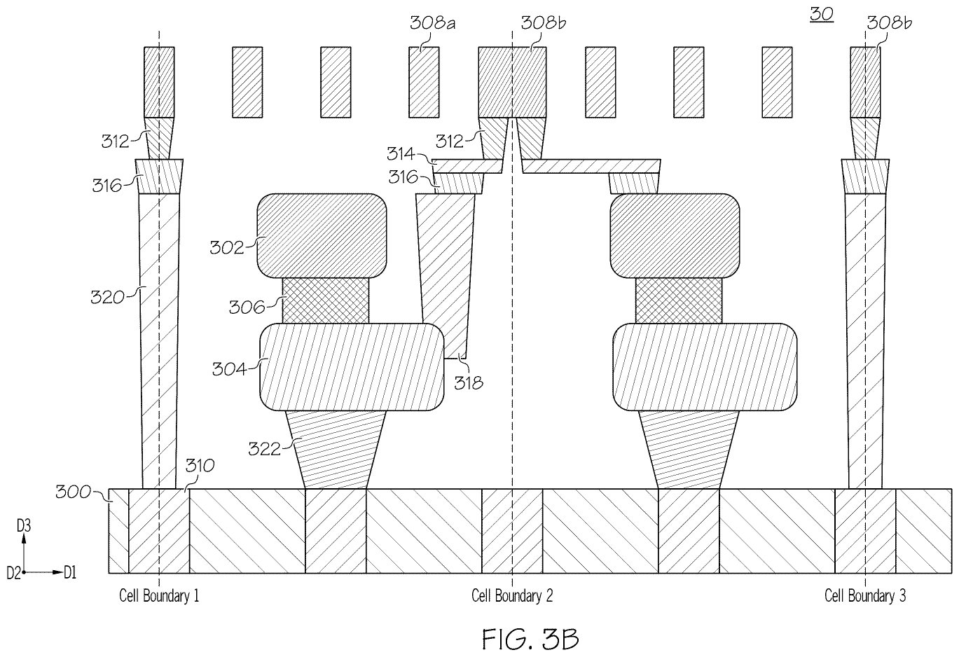

Referring to FIGS. 1A and 1B, the front-side conductive tracks 108 may be within the first cell structure. For example, the front-side conductive tracks 108 may be between the first cell boundary and the second cell boundary in the first direction D1. However, the embodiments of the front-side conductive tracks 108 are not limited thereto. For example, the front-side conductive tracks 108 may overlap the first cell boundary and/or the second cell boundary in the third direction D3 (which will be described in detail later referring to FIGS. 2A and 2B). Although six (6) front-side conductive tracks 108 between the first cell boundary and the second cell boundary (in the first cell structure) are illustrated in FIGS. 1A and 1B, the number of the front-side conductive tracks 108 is not limited thereto. In some embodiments, the front-side conductive tracks 108 may include a conductive material, such as a metal. For example, the front-side conductive tracks 108 may include copper, aluminum, and/or tungsten, but not limited thereto. In some embodiments, the front-side conductive tracks 108 may comprise a front-side signal transfer path (track) 108a and/or a FSPDN 108b (also referred to as a front-side power rail 108b) for the integrated circuit device 10. For example, the front-side signal transfer path 108a may be configured to transfer a signal to or from at least one of the first transistor 102 and the second transistor 104 through a conductive contact and/or a conductive via of the MOL structure (which will be described in detail below). In some embodiments, the front-side signal transfer path 108a in the first cell structure may be electrically disconnected from the first transistor 102 and the second transistor 104. For example, the front-side signal transfer path 108a in the first cell structure may be deactivated or may be electrically connected to an element (e.g., a transistor) of a different cell structure. The FSPDN 108b may be configured to receive power from a back-side conductive track 110 (e.g., a BSPDN 110) (which will be described in detail below) and supply power to elements in a second cell structure (which will be described in detail later referring to FIGS. 3A and 3B) adjacent the first cell structure.

The integrated circuit device 10 may include back-side conductive tracks 110 on (below)/in the substrate 100. In some embodiments, the back-side conductive tracks 110 may be in the substrate 100. In some embodiments, the back-side conductive tracks 110 may be on a lower surface of the substrate 100. For example, the integrated circuit device 10 may include back-side conductive tracks 110 on (below) the second transistor 104. Although not illustrated, an interlayer insulating layer may extend around (e.g., at least partially surround) the back-side conductive tracks 110. The back-side conductive tracks 110 may be spaced apart from each other in the first direction D1. The back-side conductive tracks 110 may be spaced apart from each other by (substantially) the same distance in the first direction D1. In some embodiments, the back-side conductive tracks 110 may be spaced apart from each other by different distances in the first direction D1. In some embodiments, each of the back-side conductive tracks 110 may have the same or substantially the same width in the first direction D1. In some embodiments, one of the back-side conductive tracks 110 may have a width in the first direction D1 different from a width of another one of the back-side conductive tracks 110 in the first direction D1. In some embodiments, the distance between adjacent ones of the back-side conductive tracks 110 in the first direction D1 may be equal or substantially equal to the width of the back-side conductive track 110 in the first direction D1.

The back-side conductive tracks 110 may be within the first cell structure. For example, the back-side conductive tracks 110 may be between the first cell boundary and the second cell boundary in the first direction D1. However, the embodiments of the back-side conductive tracks 110 are not limited thereto. For example, the back-side conductive tracks 110 may overlap the first cell boundary and/or the second cell boundary in the third direction D3. Although three (3) back-side conductive tracks 110 between the first cell boundary and the second cell boundary are illustrated in FIGS. 1A and 1B, the number of the back-side conductive tracks 110 in the first cell structure is not limited thereto. In some embodiments, the back-side conductive tracks 110 may include a conductive material, such as a metal. For example, the back-side conductive tracks 110 may include copper, aluminum, and/or tungsten, but not limited thereto. In some embodiments, the back-side conductive tracks 110 may be configured to perform as a back-side signal transfer path (track) 110 and/or a BSPDN 110 (also referred to as a back-side power rail 110) for the integrated circuit device 10. For example, the back-side conductive tracks 110 (e.g., the back-side signal transfer path 110) may be configured to transfer a signal to or from at least one of the first transistor 102 and the second transistor 104 through a conductive contact and/or a conductive via (which will be described in detail below). In some embodiments, the back-side signal transfer path 110 in the first cell structure may be electrically disconnected from the first transistor 102 and the second transistor 104. For example, the back-side signal transfer path 110 in the first cell structure may be deactivated or may be electrically connected to an element (e.g., a transistor) of another cell structure.

The BSPDN 110 may be configured to supply power to the front-side conductive track 108 (e.g., the FSPDN 108b). In some embodiments, the FSPDN 108b and the BSPDN 110 may be in different power domains. The stacked transistor structure (e.g., the power tab cell), comprising the first transistor 102 and the second transistor 104, may distinguish the power domain of the FSPDN 108b from the power domain of the BSPDN 110. For example, the power domain of the FSPDN 108b may be a local power distribution network, and the power domain of the BSPDN 110 may be a global power distribution network.

The integrated circuit device 10 may further include a middle-of-line (MOL) structure. The MOL structure may include interlayer insulating layer(s) in which conductive wire(s) (e.g., metal wire(s)), conductive via(s) (e.g., metal via(s)), and/or conductive contact(s) (e.g., metal contact(s)) are provided. Various elements of the integrated circuit device 10, such as the first transistor 102 and the second transistor 104, may be (electrically) connected to the MOL structure. In some embodiments, (at least one of) the front-side conductive tracks 108 and (at least one of) the back-side conductive tracks 110 may be electrically connected to each other through the MOL structure. The BSPDN 110 may be electrically connected to the FSPDN 108b through at least one of the first transistor 102 (e.g., the first epitaxial layer or the first source/drain layer) and the second transistor 104 (e.g., the second epitaxial layer or the second source/drain layer) and the MOL structure.

Referring to FIGS. 1A and 1B, for example, the MOL structure may include front-side conductive vias 112, a front-side upper conductive contact 114, a front-side middle conductive contact 116, a front-side lower conductive contact 118 (also referred to as an epitaxial layer contact 118), a back-side upper conductive contact 120, and a back-side lower conductive contact 122 (also referred to as a direct back-side contact (DBC) 122). However, the MOL structure is not limited to the embodiments described above. For example, the MOL structure may include an additional element that is not described above, or some of the elements of the MOL structure described above may be omitted or integrated with each other.

In some embodiments, the front-side conductive vias 112 may be between the front-side conductive tracks 108 and a transistor (e.g., the first transistor 102 and/or the second transistor 104) in the third direction D3. The front-side upper conductive contact 114 may be between (corresponding) one of the front-side conductive vias 112 and a transistor (e.g., the first transistor 102 and/or the second transistor 104) in the third direction D3. The front-side middle conductive contact 116 may be between the front-side upper conductive contact 114 and a transistor (e.g., the first transistor 102 and/or the second transistor 104) in the third direction D3. The front-side lower conductive contact 118 may be between the front-side middle conductive contact 116 and a transistor (e.g., the first transistor 102 and/or the second transistor 104) in the third direction D3. In some embodiments, the front-side lower conductive contact 118 may be in (direct) contact with (e.g., electrically connected to) the second transistor 104 (e.g., the second epitaxial layer or the second source/drain layer). The front-side lower conductive contact 118 may protrude from the second transistor 104 (e.g., the second epitaxial layer or the second source/drain layer) in the first direction D1 and/or the second direction D2. The second transistor 104 (e.g., the second epitaxial layer or the second source/drain layer) may be electrically connected to (at least one of) the front-side conductive tracks 108 (e.g., the FSPDN 108b) through the front-side lower conductive contact 118. However, the configuration of the MOL structure among the first transistor 102, the second transistor 104, the front-side conductive tracks 108, and the back-side conductive tracks 110 is not limited to the embodiments described above.

In some embodiments, the back-side upper conductive contact 120 may be between the back-side conductive tracks 110 and the front-side conductive tracks 108 in the third direction D3. In some embodiments, the back-side upper conductive contact 120 may be between the front-side middle conductive contact 116 and the back-side conductive tracks 110 in the third direction D3. The back-side lower conductive contact 122 may be between the back-side conductive tracks 110 and a transistor (e.g., the first transistor 102 and/or the second transistor 104) in the third direction D3. In some embodiments, the back-side lower conductive contact 122 may be between the second transistor 104 and the back-side conductive tracks 110 in the third direction D3. The back-side lower conductive contact 122 may be in (direct) contact with the second transistor 104 (e.g., the second epitaxial layer or the second source/drain layer). The back-side lower conductive contact 122 may be (completely) overlapped by the second transistor 104 (e.g., the second epitaxial layer or the second source/drain layer) in the third direction D3. The back-side lower conductive contact 122 may not overlap the second transistor 104 (e.g., the second epitaxial layer or the second source/drain layer) in the first direction D1 or the second direction D2. For example, the second transistor 104 (e.g., the second epitaxial layer or the second source/drain layer) may be (electrically) connected to (at least one of) the back-side conductive tracks 110 through the back-side lower conductive contact 122 in the DBC scheme. However, the configuration of the MOL structure among the first transistor 102, the second transistor 104, the front-side conductive tracks 108, and the back-side conductive tracks 110 is not limited to the embodiments described above.

Referring to FIGS. 1A and 1B, (at least one of) the back-side conductive tracks 110 (e.g., the BSPDN 110) may be electrically connected to (at least one of) the front-side conductive tracks 108 (e.g., the FSPDN 108b) through the MOL structure (e.g., the back-side lower conductive contact 122 and the front-side lower conductive contact 118) and a transistor (e.g., the second transistor 104, or the second epitaxial layer or the second source/drain layer of the second transistor 104). The stacked structure of the first transistor 102 and the second transistor 104 in the first cell structure may be configured as a power tab cell, and the second transistor 104 (e.g., the second epitaxial layer or the second source/drain layer) may be configured as a through-epi contact to deliver (supply) power from the BSPDN 110 to the FSPDN 108b.

FIGS. 2A and 2B are a plan view and a cross-sectional view of an integrated circuit device 20 with a lower through-epi connectivity and a shared front-side conductive track according to some embodiments, respectively. FIG. 2A may be a plan view from an upper side of the integrated circuit device 20. For example, FIG. 2A may be a bird's eye view of the top of the integrated circuit device 20. FIG. 2B may be a cross-sectional view (e.g., along the first direction D1) of the integrated circuit device 20 illustrated in FIG. 2A.

Since the integrated circuit device 20 may be (at least partially) formed and configured similarly as the integrated circuit device 10 in FIGS. 1A and 1B, detailed descriptions of the common configuration with the integrated circuit device 10 may be omitted, and differences from the integrated circuit device 10 will be described in detail. The substrate 200, the first transistor 202, the second transistor 204, the insulator 206, the front-side conductive tracks 208 (the front-side signal transfer path 208a and the FSPDN 208b), the back-side conductive tracks 210 (e.g., the BSPDN 210), the front-side conductive vias 212, the front-side upper conductive contact 214, the front-side middle conductive contact 216, the front-side lower conductive contact 218, the back-side upper conductive contact 220, and the back-side lower conductive contact 222 in FIGS. 2A and 2B may correspond to the substrate 100, the first transistor 102, the second transistor 104, the insulator 106 the front-side conductive tracks 108 (the front-side signal transfer path 108a and the FSPDN 108b), the back-side conductive tracks 110 (e.g., the BSPDN 110), the front-side conductive vias 112, the front-side upper conductive contact 114, the front-side middle conductive contact 116, the front-side lower conductive contact 118, the back-side upper conductive contact 120, and the back-side lower conductive contact 122 in FIGS. 1A and 1B, respectively.

Referring to FIGS. 2A and 2B, at least one of the front-side conductive tracks 208 may overlap a cell boundary (e.g., the first cell boundary or the second cell boundary) in the third direction D3. For example, the FSPDN 208b may overlap a cell boundary (e.g., the first cell boundary or the second cell boundary) in the third direction D3. In some embodiments, at least one of the back-side conductive tracks 210 (e.g., the BSPDN 210) may overlap a cell boundary (e.g., the first cell boundary or the second cell boundary) in the third direction D3. The FSPDN 208b overlapping the cell boundary may be electrically connected to the back-side conductive tracks 210 (e.g., the BSPDN 210). The back-side conductive tracks 210 (e.g., the BSPDN 210) may be configured to deliver (supply) power to the FSPDN 208b overlapping the cell boundary through the second transistor 204 (e.g., the second epitaxial layer or the second source/drain layer) and/or the MOL structure. In some embodiments, at least one of the elements of the MOL structure may overlap the cell boundary in the third direction D3. Referring to FIGS. 2A and 2B, for example, the front-side conductive via 212, the front-side upper conductive contact 214, and the back-side upper conductive contact 220 may overlap the cell boundary in the third direction D3, which the corresponding FSPDN 208b overlaps in the third direction D3, respectively.

FIGS. 3A and 3B are a plan view and a cross-sectional view of an integrated circuit device 30 illustrating multiple cell structures with a lower through-epi connectivity and a shared front-side conductive track according to some embodiments, respectively. FIG. 3A may be a plan view from an upper side of the integrated circuit device 30. For example, FIG. 3A may be a bird's eye view of the top of the integrated circuit device 30. FIG. 3B may be a cross-sectional view (e.g., along the first direction D1) of the integrated circuit device 30 illustrated in FIG. 3A.

Since the integrated circuit device 30 may be (at least partially) formed and configured similarly as the integrated circuit device 20 in FIGS. 2A and 2B, detailed descriptions of the common configuration with the integrated circuit device 20 may be omitted, and differences from the integrated circuit device 20 will be described in detail. The substrate 300, the first transistor 302, the second transistor 304, the insulator 306, the front-side conductive tracks 308 (the front-side signal transfer path 308a and the FSPDN 308b), the back-side conductive tracks 310 (e.g., the BSPDN 310), the front-side conductive vias 312, the front-side upper conductive contact 314, the front-side middle conductive contact 316, the front-side lower conductive contact 318, the back-side upper conductive contact 320, and the back-side lower conductive contact 322 in FIGS. 3A and 3B may correspond to the substrate 200, the first transistor 202, the second transistor 204, the insulator 206, the front-side conductive tracks 208 (the front-side signal transfer path 208a and the FSPDN 208b), the back-side conductive tracks 210 (e.g., the BSPDN 210), the front-side conductive vias 212, the front-side upper conductive contact 214, the front-side middle conductive contact 216, the front-side lower conductive contact 218, the back-side upper conductive contact 220, and the back-side lower conductive contact 222 in FIGS. 2A and 2B, respectively.

The integrated circuit device 30 may include a second cell structure on the substrate 300. The second cell structure may be adjacent the first cell structure in the horizontal direction (e.g., in the first direction D1). The integrated circuit device 30 may further have a third cell boundary (e.g., cell boundary 3) that is spaced apart from the second cell boundary (e.g., cell boundary 2) in the horizontal direction (e.g., the first direction D1). For example, the second cell boundary (e.g., cell boundary 2) may be between the first cell boundary (e.g., cell boundary 1) and the third cell boundary (e.g., cell boundary 3) in the first direction D1. The second cell structure may be between the second cell boundary and the third cell boundary in the first direction D1. The third cell boundary may be opposite to the second cell boundary with respect to the second cell structure in the first direction D1. For example, the second cell structure may refer to a region that includes various elements of the integrated circuit device 30 between the second cell boundary and the third cell boundary in the first direction D1.

The second cell structure that is adjacent the first cell structure in a horizontal direction (e.g., the first direction D1) may comprise (substantially) the same elements of the first cell structure described above. In some embodiments, the configurations, structures, and shapes of the elements of the second cell structure may be (substantially) the same as those of the first cell structure. However, the embodiments of the configurations, structures, and shapes of the second cell structure and the elements therein are not limited thereto. For example, some of the elements of the first cell structure described above may be modified or omitted in the second cell structure.

Referring to FIGS. 3A and 3B, at least one of the front-side conductive tracks 308 (e.g., the FSPDN 308b) overlapping the second cell boundary may be shared by the first cell structure and the second cell structure. In some embodiments, the FSPDN 308b may cross the second cell boundary in the first direction D1. At least one of the back-side conductive tracks 310 (e.g., the BSPDN 310) overlapping the second cell boundary may be shared by the first cell structure and the second cell structure. In some embodiments, the BSPDN 310 may cross the second cell boundary in the first direction D1. The BSPDN 310 in the first cell structure may be electrically connected to the first transistor 302 in the second cell structure through the second transistor 304 (e.g., the second epitaxial layer or the second source/drain layer) in the first cell structure, the MOL structures in the first cell structure and the second cell structure, and the front-side conductive track 308 (e.g., the FSPDN 308b) overlapping the second cell boundary in the third direction D3. For example, the BSPDN 310 in the first cell structure may deliver (supply) power to the first transistor 302 in the second cell structure through the second transistor 304 (e.g., the second epitaxial layer or the second source/drain layer) in the first cell structure, the MOL structures in the first cell structure and the second cell structure, and the front-side conductive track 308 (e.g., the FSPDN 308b) overlapping the second cell boundary in the third direction D3. In some embodiments, the first transistor 302 in the second cell structure may be an operable transistor. For example, the first transistor 302 in the second cell structure may operate as a switch. The first transistor 302 in the second cell structure may be switched between a conductive state (e.g., a more-conductive state) and a non-conductive state (e.g., a less-conductive state). The FSPDN 308b overlapping the second cell boundary in the third direction D3 may have a greater width in the first direction D1 than a width in the first direction D1 of another one of the front-side conductive tracks 308 (e.g., a front-side signal transfer path 308a). However, the configurations of the second cell structure are not limited to the embodiments described above. For example, the BSPDN 310 may deliver (supply) power to the second transistor 304 in the second cell structure, which may be an operable transistor, through the second transistor 304 (e.g., the second epitaxial layer or the second source/drain layer) in the first cell structure, the MOL structures in the first cell structure and the second cell structure, and the front-side conductive track 308 (e.g., the FSPDN 308b) overlapping the second cell boundary in the third direction D3.

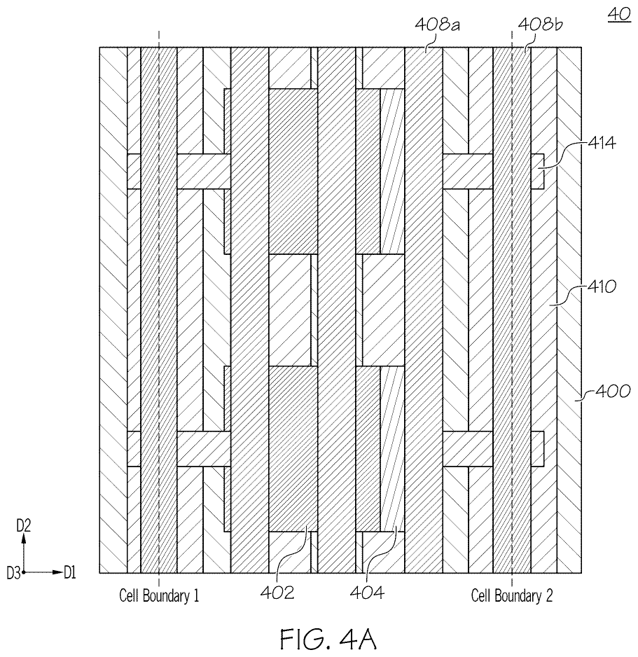

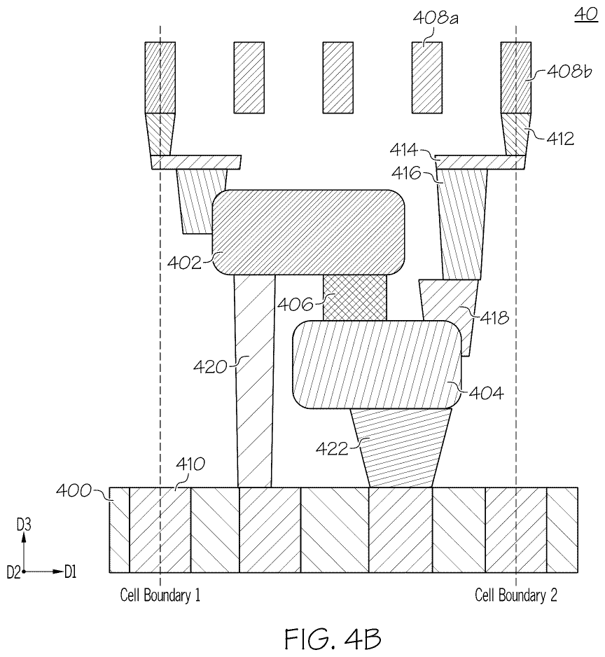

FIGS. 4A and 4B are a plan view and a cross-sectional view of an integrated circuit device 40 with a lower through-epi connectivity, an upper through-epi connectivity, and a shared front-side conductive track according to some embodiments, respectively. FIG. 4A may be a plan view from an upper side of the integrated circuit device 40. For example, FIG. 4A may be a bird's eye view of the top of the integrated circuit device 40. FIG. 4B may be a cross-sectional view (e.g., along the first direction D1) of the integrated circuit device 40 illustrated in FIG. 4A.

Since the integrated circuit device 40 may be (at least partially) formed and configured similarly as the integrated circuit device 20 in FIGS. 2A and 2B, detailed descriptions of the common configuration with the integrated circuit device 20 may be omitted, and differences from the integrated circuit device 20 will be described in detail.

The substrate 400, the first transistor 402, the second transistor 404, the insulator 406, the front-side conductive tracks 408 (the front-side signal transfer path 408a and the FSPDN 408b), the back-side conductive tracks 410 (e.g., the BSPDN 410), the front-side conductive vias 412, the front-side upper conductive contact 414, the front-side middle conductive contact 416, the front-side lower conductive contact 418, the back-side upper conductive contact 420, and the back-side lower conductive contact 422 in FIGS. 4A and 4B may correspond to the substrate 200, the first transistor 202, the second transistor 204, the insulator 206, the front-side conductive tracks 208 (the front-side signal transfer path 208a and the FSPDN 208b), the back-side conductive tracks 210 (e.g., the BSPDN 210), the front-side conductive vias 212, the front-side upper conductive contact 214, the front-side middle conductive contact 216, the front-side lower conductive contact 218, the back-side upper conductive contact 220, and the back-side lower conductive contact 222 in FIGS. 2A and 2B, respectively.

In some embodiments, the first transistor 402 and the second transistor 404 may be staggered in the first direction D1. For example, the center (or a central portion) of the first transistor 402 and the center (or a central portion) of the second transistor 404 may not overlap (e.g., may be misaligned with) each other in the third direction D3. For example, the center (or the central portion) of the first transistor 402 and the center (or the central portion) of the second transistor 404 may be offset from each other in the first direction D1. In some embodiments, the first transistor 402 may have a first sidewall and a second sidewall that is opposite to the first sidewall in the first direction D1, and the second transistor 404 may have a third sidewall and a fourth sidewall that is opposite to the third sidewall in the first direction D1. The first sidewall and the second sidewall of the first transistor 402 and the third sidewall and the fourth sidewall of the second transistor 404 may not overlap with each other in the third direction D3. For example, a plane of the second sidewall of the first transistor 402 may be between respective planes of the third sidewall and the fourth sidewall of the second transistor 404 in the first direction D1. A plane of the first sidewall of the first transistor 402 may be free of overlap with respective planes of the third sidewall and the fourth sidewall of the second transistor 404 in the third direction D3. The first sidewall of the first transistor 402 may be free of overlap with the second transistor 404 in the third direction D3. For example, a plane of the third sidewall of the second transistor 404 may be between respective planes of the first sidewall and the second sidewall of the first transistor 402 in the first direction D1. For example, a plane of the third sidewall of the second transistor 404 may overlap the first transistor 402 in the third direction D3. A plane of the fourth sidewall of the second transistor 404 may be free of overlap with respective planes of the first sidewall and the second sidewall of the first transistor 402 in the third direction D3. The fourth sidewall of the second transistor 404 may be free of overlap with the first transistor 402 in the third direction D3. In summary, the first transistor 402 may have a portion that is free of overlap with the second transistor 404 in the third direction D3, and the second transistor 404 may have a portion that is free of overlap with the first transistor 402 in the third direction D3. However, the relative locations of the first transistor 402 and the second transistor 404 are not limited to the embodiments described above. The staggered (zigzag) structure of the first transistor 402 and the second transistor 404 may be referred to as a Z-shape scheme or a Z-shape 3D stacked device (e.g., Z-shape 3D stacked field effect transistor (Z-shape 3DSFET)).

Referring to FIGS. 4A and 4B, the front-side conductive track 408b (e.g., the FSPDN 408b) overlapping the first cell boundary in the third direction D3 may be electrically connected to (at least one of) the back-side conductive tracks 410 (e.g., the BSPDN 410) through the first transistor 402 (e.g., the first epitaxial layer or the first source/drain layer) and the MOL structure. For example, the first transistor 402 (e.g., the first epitaxial layer or the first source/drain layer) may be electrically connected to (at least one of) the back-side conductive tracks 410 (e.g., the BSPDN 410) through the back-side upper conductive contact 420. The back-side upper conductive contact 420 may overlap the first transistor 402 in the third direction D3 and may not overlap the first transistor 402 in a horizontal direction (e.g., the first direction D1 and/or the second direction D2). The back-side upper conductive contact 420 may be in the DBC scheme. In some embodiments, the first transistor 402 may be inoperable. The back-side conductive track 410 (e.g., the BSPDN 410) may deliver (supply) power to the front-side conductive track 408 (e.g., the FSPDN 408b) through the first transistor 402 (e.g., the first epitaxial layer or the first source/drain layer) and the MOL structure.

Example embodiments described herein may improve design flexibility and distinguish power domains of an integrated circuit device by utilizing at least one of the transistors (e.g., an epitaxial layer or a source/drain layer of the transistor) in a stacked transistor structure as a through-epi contact to deliver power from the BSPDN to the FSPDN, while the integration degree of the integrated circuit device is being improved (e.g., maximized) by utilizing the stacked transistor structure, the BSPDN, and the DBC scheme. However, it will be understood that the embodiments, goals, and benefits of the present disclosure are not limited to the descriptions above.

Example embodiments are described herein with reference to the accompanying drawings. Many different forms and embodiments are possible without deviating from the teachings of this disclosure and so the disclosure should not be construed as limited to the example embodiments set forth herein. Rather, these example embodiments are provided so that this disclosure will be thorough and complete, and will convey the scope of the present inventive concepts to those skilled in the art. In the drawings, the sizes and relative sizes of layers and regions may be exaggerated for clarity. Like reference numbers may refer to like elements throughout unless clearly stated otherwise.

Example embodiments are described herein with reference to cross-sectional illustrations that are schematic illustrations of idealized embodiments and intermediate structures of example embodiments. As such, variations from the shapes of the illustrations as a result, for example, of manufacturing techniques and/or tolerances, are to be expected. Thus, embodiments herein should not be construed as limited to the particular shapes illustrated herein but may include deviations in shapes that result, for example, from manufacturing.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein, the term “and/or” includes any and all combinations of one or more of the associated listed items. Moreover, the symbol “/” (e.g., when used in the term “source/drain”) will be understood to be equivalent to the term “and/or.”

As used herein, “an element A overlapping an element B in a direction X” (or similar language) means that there is at least one line that extends in the direction X and intersects both the elements A and B.

It will be understood that although the terms “first,” “second,” etc. may be used herein to describe various elements, these elements should not be limited by these terms. These terms are only used to distinguish one element from another. Thus, a first element could be termed a second element without departing from the teachings of the present embodiments.

Many different embodiments have been disclosed herein, in connection with the above description and the drawings. It will be understood that it would be unduly repetitious and obfuscating to literally describe and illustrate every combination and sub-combination of these embodiments. Accordingly, the present specification, including the drawings, shall be construed to constitute a complete written description of all combinations and sub-combinations of the embodiments described herein, and of the manner and process of making and using them, and shall support claims to any such combination or sub-combination.

The above-disclosed subject matter is to be considered illustrative, and not restrictive, and the appended claims are intended to cover all such modifications, enhancements, and other embodiments, which fall within the scope of the present inventive concepts. Thus, to the maximum extent allowed by law, the scope is to be determined by the broadest permissible interpretation of the following claims and their equivalents, and shall not be restricted or limited by the foregoing detailed description.

What is claimed is:

1. An integrated circuit device comprising:
a substrate; and
a cell structure on an upper surface of the substrate,
wherein the cell structure comprises:
a first epitaxial layer on the upper surface of the substrate;
a second epitaxial layer stacked on the first epitaxial layer in a first direction that is perpendicular to the upper surface of the substrate;
a front-side conductive track on an upper portion of the cell structure; and
a back-side conductive track on a lower portion of the cell structure opposite to the upper portion of the cell structure in the first direction,
wherein the first epitaxial layer and the second epitaxial layer are between the front-side conductive track and the back-side conductive track in the first direction, and
wherein the back-side conductive track is electrically connected to the front-side conductive track through the second epitaxial layer.

2. The integrated circuit device of claim 1, further comprising:
a back-side lower conductive contact between the second epitaxial layer and the back-side conductive track in the first direction,
wherein the back-side lower conductive contact is free of overlap with the second epitaxial layer in a second direction that is parallel with the upper surface of the substrate, and
wherein the second epitaxial layer is electrically connected to the back-side conductive track through the back-side lower conductive contact.

3. The integrated circuit device of claim 2, further comprising:
an epitaxial layer contact between the second epitaxial layer and the front-side conductive track in the first direction,
wherein the epitaxial layer contact protrudes from the second epitaxial layer in the second direction, and
wherein the second epitaxial layer is electrically connected to the front-side conductive track through the epitaxial layer contact.

4. The integrated circuit device of claim 3, wherein one of sidewalls of the first epitaxial layer overlaps the second epitaxial layer in the first direction.

5. The integrated circuit device of claim 4, wherein the first epitaxial layer has a first width in the second direction,
wherein the second epitaxial layer has a second width in the second direction, and
wherein the second width is different from the first width.

6. The integrated circuit device of claim 5, wherein the second width is greater than the first width.

7. The integrated circuit device of claim 6, wherein another one of the sidewalls of the first epitaxial layer aligns one of sidewalls of the second epitaxial layer in the second direction.

8. The integrated circuit device of claim 1, wherein the back-side conductive track is configured to supply power to the front-side conductive track through the second epitaxial layer.

9. An integrated circuit device comprising:
a substrate; and
a cell structure on an upper surface of the substrate,
wherein the cell structure comprises:
a first transistor including a first source/drain layer on the upper surface of the substrate;
a second transistor including a second source/drain layer stacked on the first source/drain layer in a first direction that is perpendicular to the upper surface of the substrate;
front-side power rails on an upper portion of the cell structure; and
back-side power rails on a lower portion of the cell structure,
wherein the first source/drain layer and the second source/drain layer are between the front-side power rails and the back-side power rails in the first direction, and
wherein at least one of the back-side power rails is electrically connected to at least one of the front-side power rails through the second source/drain layer.

10. The integrated circuit device of claim 9, wherein the second transistor is inoperable.

11. The integrated circuit device of claim 9, further comprising:
a back-side lower conductive contact between the second source/drain layer and the back-side power rails in the first direction,
wherein the back-side lower conductive contact is free of overlap with the second source/drain layer in a second direction that is parallel with the upper surface of the substrate,
wherein the at least one of the back-side power rails is electrically connected to the at least one of the front-side power rails through the second source/drain layer, and
wherein the second source/drain layer is electrically connected to the at least one of the back-side power rails through the back-side lower conductive contact.

12. The integrated circuit device of claim 11, further comprising:
an epitaxial layer contact between the second source/drain layer and the front-side power rails in the first direction,
wherein the epitaxial layer contact protrudes from the second source/drain layer in the second direction, and
wherein the second source/drain layer is electrically connected to the at least one of the front-side power rails through the epitaxial layer contact.

13. The integrated circuit device of claim 12, wherein one of sidewalls of the first source/drain layer overlaps the second source/drain layer in the first direction.

14. The integrated circuit device of claim 13, wherein another one of the sidewalls of the first source/drain layer aligns one of sidewalls of the second source/drain layer in the second direction.

15. The integrated circuit device of claim 14, wherein the at least one of the back-side power rails is configured to supply power to the at least one of the front-side power rails through the second source/drain layer.

16. An integrated circuit device comprising:
a substrate;
a first cell structure on an upper surface of the substrate;
a second cell structure adjacent the first cell structure in a first direction that is parallel with the upper surface of the substrate; and
a cell boundary between the first cell structure and the second cell structure in the first direction,
wherein the first cell structure comprises:
a first transistor including a first epitaxial layer on the upper surface of the substrate;
a second transistor including a second epitaxial layer stacked on the first epitaxial layer in a second direction that is perpendicular to the upper surface of the substrate;
front-side conductive tracks on an upper surface of the first transistor; and
back-side conductive tracks on a lower surface of the second transistor,
wherein at least one of the back-side conductive tracks is electrically connected to at least one of the front-side conductive tracks through the second epitaxial layer, and
wherein the second transistor is inoperable.

17. The integrated circuit device of claim 16, further comprising:
a back-side lower conductive contact between the second epitaxial layer and the back-side conductive tracks in the second direction,
wherein the back-side lower conductive contact is free of overlap with the second epitaxial layer in the first direction,
wherein the at least one of the back-side conductive tracks is electrically connected to the at least one of the front-side conductive tracks through the second epitaxial layer, and
wherein the second epitaxial layer is electrically connected to the at least one of the back-side conductive tracks through the back-side lower conductive contact.

18. The integrated circuit device of claim 17, further comprising:
an epitaxial layer contact between the second epitaxial layer and the front-side conductive tracks in the second direction,
wherein the epitaxial layer contact protrudes from the second epitaxial layer in the first direction, and
wherein the second epitaxial layer is electrically connected to the at least one of the front-side conductive tracks through the epitaxial layer contact.

19. The integrated circuit device of claim 18, wherein the at least one of the front-side conductive tracks overlaps the cell boundary in the second direction.

20. The integrated circuit device of claim 19, wherein the at least one of the back-side conductive tracks is configured to supply power to the first cell structure and the second cell structure through the second epitaxial layer and the at least one of the front-side conductive tracks, and
wherein the second cell structure includes an operable transistor.
